(19) United States
(12) Patent Application Publication
(10) Pub. No.: US 2005/0282378 A1
(43) Pub. Date: Dec. 22, 2005

(54) Interconnects forming method and interconnects forming apparatus

(76) Inventors: Akira Fukunaga, Tokyo (JP); Manabu Tsujimura, Tokyo (JP); Hiroaki Inoue, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/941,882

(22) Filed: Sep. 16, 2004

(30) Foreign Application Priority Data
Jun. 22, 2004 (JP) 2004-184239
Sep. 8, 2004 (JP) 2004-261247

(51) Int. Cl. H01L 21/4763; C23C 16/00

(52) U.S. Cl. 438/622; 118/715

(57) ABSTRACT

An interconnects forming method and an interconnects forming apparatus are useful for embedding a conductive material (interconnect material), such as copper or silver, into interconnect recesses provided in a surface of a substrate, such as a semiconductor wafer, to thereby form embedded interconnects, and selectively covering the surfaces of embedded interconnects with a metal film (protective film) to provide a multi-level structure. The interconnects forming method comprises: providing a substrate which has been prepared by forming a barrier layer over a substrate surface having interconnect recesses formed in an insulating film, and then forming a film of an interconnect material in the interconnect recesses and over the substrate surface; removing extra interconnect material formed over the substrate surface, thereby forming interconnects with the interconnect material embedded in the interconnect recesses and making the barrier layer present in the other portion than the interconnect-formed portion exposed; and forming a metal film selectively on surfaces of interconnects.

### BACKGROUND OF THE INVENTION

1. Field of the Invention

The present invention relates to an interconnects forming method and an interconnects forming apparatus, and more particularly to an interconnects forming method and an interconnects forming apparatus which are useful for embedding a conductive material (interconnect material), such as copper or silver, into interconnect recesses provided in a surface of a substrate, such as a semiconductor wafer, to thereby form embedded interconnects, and selectively covering surfaces of the embedded interconnects with a metal film (protective film) to provide a multi-level structure.

2. Description of the Related Art

As a process for forming interconnects in a semiconductor device, a process (so-called “damascene process”), which comprises embedding an interconnect material (metal) into trenches and via holes, is coming into practical use. According to this process, an interconnect material (metal) such as aluminum or, more recently, copper or silver, is embedded into trenches and via holes, which have previously been formed in an inter-level dielectric layer. Thereafter, extra metal is removed by chemical-mechanical polishing (CMP) so as to flatten a surface of the substrate.

In a case of interconnects formed by such a process, for example, copper interconnects formed by using copper as an interconnect material, embedded copper interconnects have exposed surfaces after performing a flattening processing. In order to prevent thermal diffusion of such interconnects (copper), or to prevent oxidation of such interconnects (copper) e.g. during forming thereon an insulating film (oxide film) under an oxidizing atmosphere later to produce a semiconductor device having a multi-level interconnect structure, it is now under study to selectively cover the exposed surfaces of interconnects with an protective film (cap material) composed of a Co alloy, a Ni alloy, or the like so as to prevent thermal diffusion and oxidation of interconnects. Such a protective film of a Co alloy, a Ni alloy, or the like can be produced e.g. by performing electroless plating.

A protective film of W or VN could conceivably be selectively formed on interconnects by a CVD method or the like to solve the same objects.

FIGS. 1A through 1D illustrate, in a sequence of process steps, an example of forming copper interconnects in a semiconductor device. As shown in FIG. 1A, an insulating film (interlevel dielectric film) 2 of, for example, SiO₂ or a low-k material is deposited on a conductive layer la formed on a semiconductor base 1 having formed semiconductor devices. Via holes 3 and trenches 4 are formed in the insulating film 2 by performing a lithography/etching technique so as to provide interconnect recesses. Thereafter, a barrier layer 5 of TaN or the like is formed on the insulating film 2, and a seed layer 6 as a electric supply layer for electroplating is formed on the barrier layer 5 by sputtering or the like.

Then, as shown in FIG. 1B, copper plating is performed on a surface of a substrate W to fill the via holes 3 and the trenches 4 with copper and, at the same time, deposit copper 7 on the insulating film 2. Thereafter, the barrier layer 5, the seed layer 6 and the copper 7 on the insulating film 2 are removed by chemical-mechanical polishing (CMP) or the like so as to leave copper filled in the via holes 3 and the trenches 4, and have a surface of the insulating film 2 lie substantially on the same plane as this copper. Interconnects (copper interconnects) 8 composed of the seed layer 6 and the copper 7 are thus formed in the insulating film 2, as shown in FIG. 1C.

Then, as shown in FIG. 1D, electroless plating is performed on a surface of the substrate W to selectively form a protective film 9 of a Co alloy, a Ni alloy, or the like on surfaces of interconnects 8, thereby covering and protecting the surfaces of interconnects 8 with the protective film 9.

According to such a conventional process, a metal film for selectively covering and protecting the surfaces of interconnects is formed on interconnects when the surface of an insulating film is exposed after the removal of an interconnect material (copper and seed layer) and a barrier layer on the insulating film. The insulating film (interlevel dielectric film) after the removal of barrier layer, depending on its material, has poor wettability. Thus, when forming the metal film by plating, it is necessary to individually set process conditions for a particular insulating film material.

Polishing of a barrier layer is commonly carried out by a method mainly utilizing mechanical polishing with an abrasive. With the recent trend toward highly-integrated devices in the field of semiconductor industry, there is a tendency to use as an insulating film a porous low-k material having a very low mechanical strength. Such an insulating film of very low mechanical strength can be easily destroyed by a pressing force applied thereto during polishing of a barrier layer by a method mainly utilizing mechanical polishing with an abrasive.

### SUMMARY OF THE INVENTION

The present invention has been made in view of the above situation in the related art. It is therefore an object of the present invention to provide an interconnects forming method and an interconnects forming apparatus which can form a metal film selectively on surfaces of interconnects without changing the process conditions depending on different insulating film materials and which can remove a barrier layer that has become unnecessary by a method with a relatively small mechanical factor.

In order to achieve the above object, the present invention provides an interconnects forming method comprising: providing a substrate which has been prepared by forming a barrier layer over a substrate surface having interconnect recesses formed in an insulating film, and then forming a film of an interconnect material in the interconnect recesses and over the substrate surface; removing extra interconnect material formed over the substrate surface, thereby forming interconnects with the interconnect material embedded in the interconnect recesses and making the barrier layer present in the other portion than the interconnect-formed portion exposed; and forming a metal film selectively on surfaces of interconnects.

The barrier layer, which has become exposed on the substrate surface after the removal of the extra interconnect material formed over the substrate surface, is generally covered with a native oxide film and is thus free from the problem of poor wettability. Accordingly, leaving the barrier layer as a mask can eliminate the need to ensure the wettability of the substrate surface when forming a metal film by plating selectively on surfaces of interconnects. In case a metal film is formed by a chemical vapor deposition method, the metal film can be prevented from being formed on the surface of the barrier layer and can be formed selectively on the surfaces of interconnects.

Should the film-forming selectivity of metal film be insufficient and a quantity of metal film be formed on the barrier layer, the unnecessary metal film can be removed together with the barrier layer in a later process step, thus securing a sufficient film-forming selectivity of the metal film.

The removal of the extra interconnect material from the substrate surface is preferably carried out in such a manner that the surfaces of interconnects formed in the interconnect recesses becomes lower than the surface of the insulating film.

By removing the interconnect material such that the surfaces of interconnects formed in the interconnect recesses becomes lower than the surface of the insulating film and forming a metal film on the surfaces of interconnects such that the surface of the metal film becomes substantially flush with the surface of the insulating film, it becomes possible to provide a flat substrate surface after removing the barrier layer.

The metal film may be formed by, for example, a chemical vapor deposition method.

When forming the metal film by a chemical vapor deposition method utilizing the barrier layer as a mask, the metal film can be formed selectively only on the surfaces of interconnects while preventing the formation of the metal film on the surface of the barrier layer.

The metal film may also be formed by a plating method.

When forming the metal film by a plating method utilizing the barrier layer, which is free from the problem of poor wettability, as a mask, the metal film can be formed selectively only on the surfaces of interconnects under the same process conditions irrespective of differences in insulating film materials.

The barrier layer on the insulating film may be removed after the selective formation of the metal film on the surfaces of interconnects.

By removing only the barrier layer using the metal film as a mask, the barrier layer can be removed by a method with a relatively small mechanical factor. Accordingly, even when the insulating film is made of a material having a very low mechanical strength, such as a low-k material, the barrier layer, which has become unnecessary, can be removed securely without damage to the insulating film.

Furthermore, the metal film has been formed on the surfaces of interconnects to protect interconnects prior to the removal of the barrier layer. This can enrich process options for the removal of the barrier layer, enabling a variety of removal methods to be employed.

The removal of the barrier layer on the insulating film is carried out, for example, by polishing.

It is preferred that the polishing be performed by CMP or electrolytic polishing with a relatively small mechanical factor as compared to a chemical factor.

The removal of the barrier layer on the insulating film may be carried out by etching with a chemical or plasma etching.

Such a method can remove the barrier layer without resorting to a mechanical factor.

The selective formation of the metal film on the surfaces of interconnects is preferably carried out in such a manner that the surface of the metal film remains lower than the surface of the insulating film.

By removing the interconnect material in such a manner that the surfaces of interconnects formed in the interconnect recesses becomes lower than the surface of the insulating film and that the level difference is larger than the thickness of the metal film to be formed selectively on interconnects, the selective formation of the metal film on the surfaces of interconnects can be carried out in such a manner that the surface of the metal film remains lower than the surface of the insulating film. The interconnect portion after the removal of the barrier layer can thus be prevented from protruding from the substrate surface.

After the removal of the barrier layer on the insulating film, the insulating film may be partly removed.

By partly removing the insulating film after the removal of the barrier layer on the insulating film, it becomes possible to completely remove the barrier layer on the insulating film, thus preventing part of the barrier layer from remaining on the insulating film.

The partial removal of the insulating film is preferably carried out in such a manner that the surface of the insulating film and the surface of the metal film make a substantially flat plane.

This can prevent part of the barrier layer from remaining on the insulating film and can provide a flat substrate surface after the partial removal of the insulating film.

The removal of the insulating film is preferably carried out by etching with a chemical or plasma etching.

As with the case of the barrier layer, such a method can remove the insulating film without resorting to a mechanical factor.

The present invention also provides an interconnects forming apparatus comprising: a loading/unloading section for mounting a cassette for housing a substrate; a transport robot for transporting the substrate; a wet etching unit for etching an entire surface of the substrate with a chemical; a pretreatment unit for carrying out a pre-electroless plating treatment of the surface of the substrate; an electroless plating unit for carrying out electroless plating of the surface of the substrate; and a cleaning unit for cleaning the surface of the substrate.

The interconnects forming apparatus may further comprise a chemical-mechanical polishing unit.

### BRIEF DESCRIPTION OF THE DRAWINGS

FIGS. 1A through 1D are diagrams illustrating, in a sequence of process steps, an example of forming copper interconnects in a semiconductor device;

FIG. 2 is a diagram schematically showing a substrate after the formation of a film of an interconnect material;

FIGS. 3A through 3C are diagrams illustrating, in a sequence of process steps, an interconnects forming method according to an embodiment of the present invention;

FIGS. 4A through 4C are diagrams illustrating, in a sequence of process steps, an interconnects forming method according to another embodiment of the present invention;

FIGS. 5A through 5C are diagrams illustrating, in a sequence of process steps, an interconnects forming method according to yet another embodiment of the present invention;

FIG. 6 is a layout plan view of an interconnects forming apparatus according to an embodiment of the present invention;

FIG. 7 is a layout plan view of an interconnects forming apparatus according to another embodiment of the present invention; and

FIG. 8 is a layout plan view of an interconnects forming apparatus according to yet another embodiment of the present invention.

### DETAILED DESCRIPTION OF THE PREFERRED EMBODIMENTS

Preferred embodiments of the present invention will now be described with reference to the drawings. The following description illustrates the formation of copper interconnects using copper as an interconnect material. A conductive material other than copper, such as a copper alloy, silver or a silver alloy, may also be used as an interconnect material.

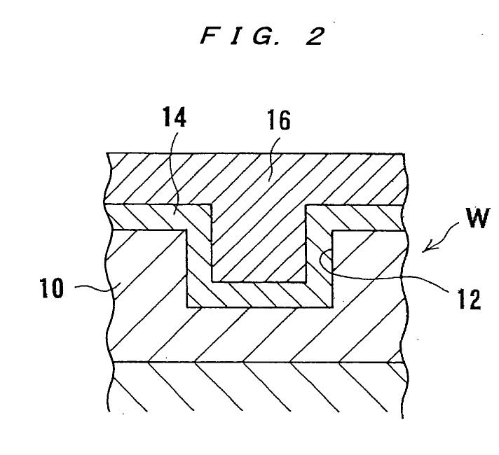

FIG. 2 schematically shows a substrate usable in an interconnects forming method of the present invention. As shown in FIG. 2, trenches 12 as interconnect recesses are formed, for example, by the lithography/etching technique, in an insulating film (interlevel insulating film) 10 of, for example, SiO₂ or a low-k material deposited on a substrate W, and a barrier layer 14 of TaN, Ta, TiN, WN, or the like is formed by sputtering, ALD (atomic layer deposition), or the like over substantially the entire surface of the insulating film 10. A film of copper (interconnect material) 16 is formed, for example, by plating, CVD, or the like over the surface of the substrate W, thereby embedding copper in the trenches (interconnect recesses) 12 and depositing copper on the insulating film 10.

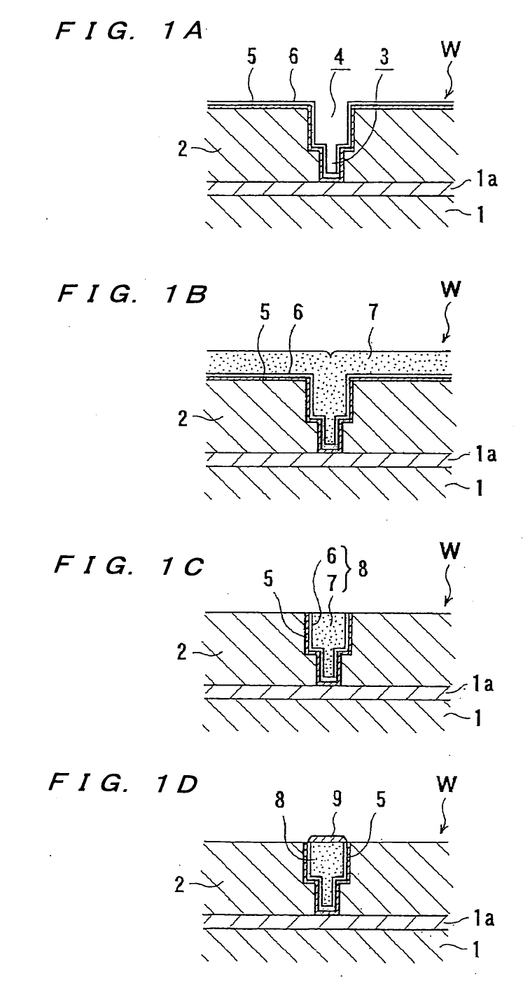

In the case of forming a film of an interconnect material such as copper by carrying out electroplating of the surface of the substrate W, a seed layer as an electric supply layer is formed on a barrier layer in advance as in the above-described conventional process shown in FIG. 1A.

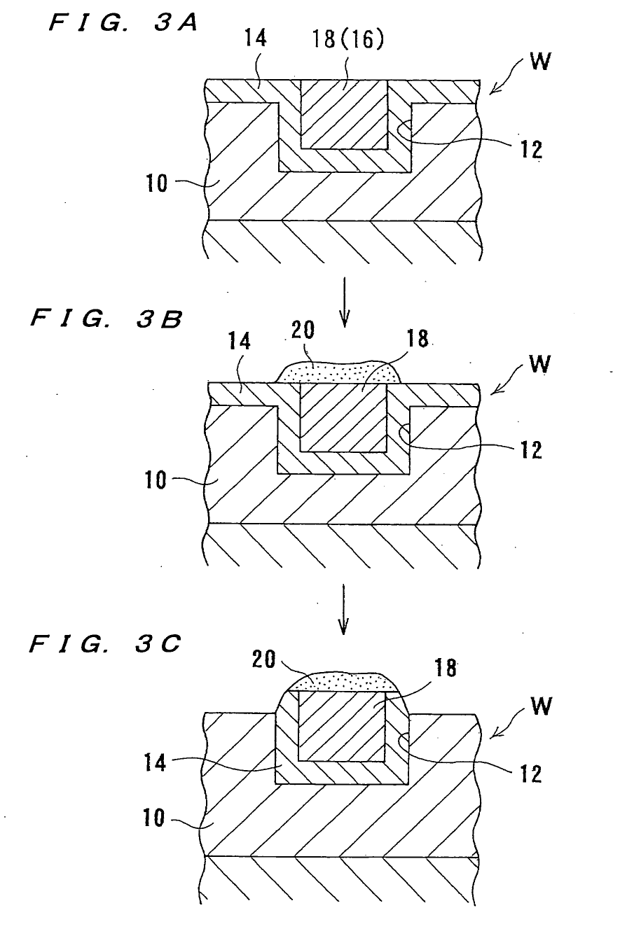

FIGS. 3A through 3C illustrate, in a sequence of process steps, an interconnects forming method according to an embodiment of the present invention. First, extra copper (interconnect material) 16 formed over the surface of the substrate W is polished and removed by CMP or electrolytic polishing, thereby forming interconnects 18 with the copper 16 embedded in the trenches (interconnect recesses) 12 and making exposed the barrier layer 14 present in the other portion than the interconnect-formed portion, as shown in FIG. 3A. In particular, the surface of the copper 16 is polished away, leaving the barrier layer 14, so that the surfaces of interconnects 18 in the trenches 12 becomes substantially flush with the surface of the barrier layer 14.

The removal of the extra copper 16 may also be carried out by etching using an inorganic or organic acid.

Using the barrier layer 14 thus left as a mask, a metal film (protective film) 20 of, for example, a cobalt alloy or a nickel alloy is formed selectively on the surfaces of interconnects 18 in the trenches 12, as shown in FIG. 3B, thereby covering the surfaces of interconnects 18 with the metal film 20 to protect interconnects 18.

The formation of the metal film 20 is carried out, for example, by electroless plating, chemical vapor deposition (CVD) or physical vapor deposition (PVD). In the case of carrying out the formation of the metal film 20 by electroless plating, a necessary pretreatment, for example for application of a catalyst such as Pd, is carried out so that the metal film 20 can be formed selectively on the surfaces of interconnects 18 in the trenches 12. It is possible to carry out such a pre-plating treatment simultaneously with the above-described removal of the extra copper 16.

Thereafter, the surface of the substrate W is brought into contact with a plating solution to carry out plating. Since the surface region of the substrate W except the interconnect-formed portion is covered with the barrier layer 14 which is generally covered with a spontaneous oxide film and thus is fee from the problem of poor wettability, there is no need to secure the wettability of the surface of the substrate W. Accordingly, the metal film 20 can be formed selectively only on the surfaces of interconnects 18 under the same process conditions irrespective of differences in materials that may be employed for the insulating film 10.

In the case of carrying out the formation of the metal film 20 by chemical vapor deposition, the substrate W is placed in a chamber, and the metal film 20 is allowed to grow selectively on the surfaces of interconnects 18 in the trenches 12 through chemical reactions in the vapor phase and at the surface of the substrate W. Also in this case, the surface region of the substrate W except the interconnect-formed portion is covered with the barrier layer 14. The barrier layer 14 serves as a mask to prevent the formation of a metal film on the surface of the barrier layer 14, whereby the metal film 20 can be formed selectively only on the surfaces of interconnects 18.

Next, only the barrier layer 14 on the insulating film 10, exposed on the surface of the substrate W, is selectively removed by CMP or etching, thereby completing the formation of interconnects 18 of copper whose surfaces are selectively covered and protected with the metal film 20, as shown in FIG. 3C. Since only the barrier layer 14 is removed by using the metal film 20 as a mask, the barrier layer 14 can be removed by a method with a relatively small mechanical factor. It is to be noted in this regard that the metal film 20 has been formed on the surfaces of interconnects 18 to protect interconnects 18 prior to the removal of the barrier layer 14. This can enrich process options for the removal of the barrier layer 14, enabling a variety of removal methods to be employed. For example, in the case of using CMP, which is a practical method for removal of the barrier layer 14, it is possible to employ CMP with a relatively small mechanical factor as compared to a chemical factor. Electrolytic polishing may also be employed. Further, it is also possible to employ etching with a chemical or plasma etching. Such a method can remove the barrier layer without resorting to a mechanical factor.

In the case of wet etching, no physical force is applied to a substrate. Accordingly, there is no fear of damage to the substrate even when a weak material, such as copper or a low-k material, is present in the substrate. In the case of a CMP method, on the other hand, processing of a substrate is carried out while applying a load on the substrate, and there is therefore a fear of damage to the substrate. Accordingly, it is necessary with a CMP method to use a slurry having a strong chemical reactivity and carry out polishing at a low pressure and a low speed. As regards electrolytic polishing, as with wet etching, substantially no load is applied on a substrate, and therefore there is no fear of damage to the substrate.

Accordingly, even when the insulating film 10 is made of a material having a very low mechanical strength, such as a low-k material, the barrier layer 14, which has become unnecessary, can be removed securely without damage to the insulating film 10.

Furthermore, should the film-forming selectivity of the metal film be insufficient and a quantity of metal film be formed on the barrier layer, the unnecessary metal film can be removed together with the barrier layer, thus securing a sufficient film-forming selectivity of the metal film.

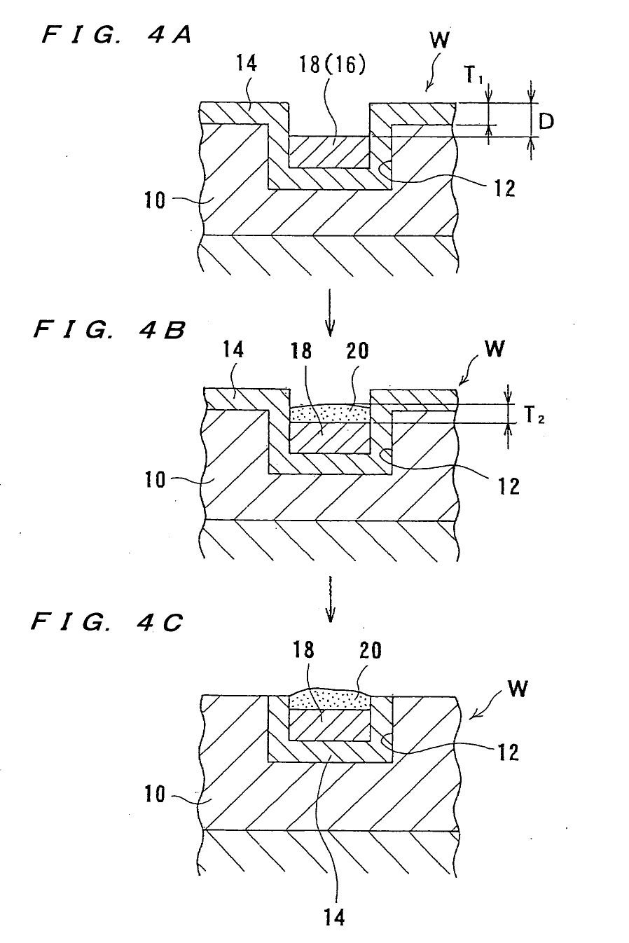

FIGS. 4A through 4C illustrate, in a sequence of process steps, an interconnects forming method according to another embodiment of the present invention. First, extra copper (interconnect material) 16 formed over the surface of the substrate W is polished and removed by CMP, electrolytic polishing or etching, thereby forming interconnects 18 with the copper 16 embedded in the trenches (interconnect recesses) 12 and making exposed the barrier layer 14 present in the other portion than the interconnect-formed portion, as shown in FIG. 4A. The removal of the extra copper 16 is carried out in such a manner that after the surfaces of interconnects 18 in the trenches 12 have become substantially flush with the surface of the exposed barrier layer 14, polishing or etching of interconnects 18 is further continued so that the surfaces of interconnects 18 formed in the trenches 12 become lower than the surface of the exposed barrier layer 14.

The distance D between the surface of the barrier layer 14 and the surfaces of interconnects 18 is determined taking account of the thickness of the barrier layer 14 and the necessary thickness of a metal film 20 to be formed selectively on the surfaces of interconnects 18, as described below, and is preferably made larger than the thickness T₁ of the barrier layer 14 (D>T₁). More preferably, the distance D is made almost equal to the sum of the thickness T₁ of the barrier layer 14 and the thickness T₂ (see FIG. 4B) of the metal film 20 to be formed on the surfaces of interconnects (D≈T₁+T₂). For example, when the thickness T₁ of the barrier layer 14 is 10 nm and the necessary thickness T₂ of the metal film 20 is 10 nm, the distance D between the surface of the barrier layer 14 and the surfaces of interconnects 18 is made 20 nm. This can prevent protrusion of the metal film 20 from the surface of the substrate W after the removal of the barrier layer 14 that has become unnecessary, and can thus provide the substrate W with a flat surface.

Using the barrier layer 14 thus left as a mask, a metal film (protective film) 20 of, for example, a cobalt alloy or a nickel alloy is formed selectively on the surfaces of interconnects 18 in the trenches 12, as shown in FIG. 4B, thereby covering the surfaces of interconnects 18 with the metal film 20 to protect interconnects 18.

Next, only the barrier layer 14 on the insulating film 10, exposed on the surface of the substrate W, is selectively removed by CMP or etching, thereby completing the formation of interconnects 18 of copper whose surfaces are selectively covered and protected with the metal film 20, as shown in FIG. 4C. By making the distance D between the surface of the barrier layer 14 and the surfaces of interconnects 18 after the removal of the unnecessary copper almost equal to the sum of the thickness T₁ of the barrier layer 14 and the thickness T₂ of the metal film 20 to be formed on the surfaces of interconnects 18 (D≈T₁+T₂), as described above, the surface of the substrate W after the removal of the barrier layer 14, which has become unnecessary, can be made flat.

It is also possible to make the distance D between the surface of the barrier layer 14 and the surfaces of interconnects 18 after the removal of the unnecessary copper larger than the sum of the thickness T₁ of the barrier layer 14 and the thickness T₂ of the metal film 20 to be formed on the surfaces of interconnects 18 (D>T₁+T₂). This can prevent the interconnect portion, consisting of interconnects 18 and the metal film 20 formed thereon, from protruding from the substrate surface after the removal of the barrier layer 14.

In the formation of interconnects in the next 65 nm-node generation and the following generations, for example, the least possible surface irregularities of a substrate is required. Accordingly, also in the case of using the metal film 20 formed on interconnects 18, for example as an adhesive layer for improved reliability, protrusion of the metal film 20, for example at a height of not less than 10 nm, is undesirable. According to this embodiment, the above requirement can be met by making flat the surface of the substrate W after the removal of the barrier layer 14 which has become unnecessary, or by preventing the interconnect portion from protruding from the substrate surface.

Also in the case of removing the barrier layer 14 using the selectively-formed metal film 20 as a mask, protrusion of interconnects 18 from the plane extending from the surface of the insulating film 10 after the removal of the barrier layer 14 is likewise undesirable. For example, by making the distance D between the surface of the barrier layer 14 and the surfaces of interconnects 18 after the removal of the unnecessary copper almost equal to the thickness T, of the barrier layer 14 (D≈T₁), the surface of the insulating film 10 can be made substantial flush with the surfaces of interconnects 18 after the removal of the barrier layer 14 which has become unnecessary, thus preventing interconnects 18 from protruding from the plane extending from the surface of the insulating film 10.

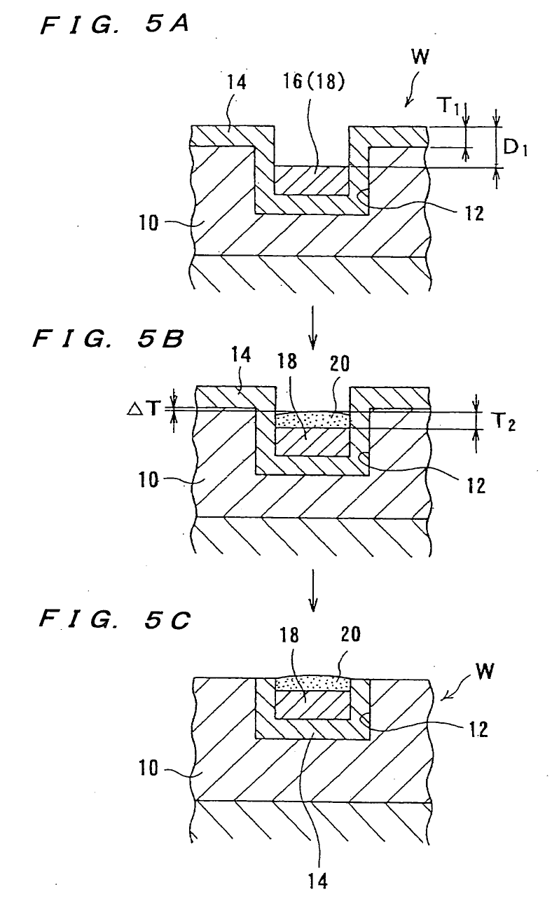

FIGS. 5A through 5C illustrate, in a sequence of process steps, an interconnects forming method according to yet another embodiment of the present invention. First, extra copper (interconnect material) 16 formed over the surface of the substrate W is polished and removed by CMP, electrolytic polishing or etching, thereby forming interconnects 18 with the copper 16 embedded in the trenches (interconnect recesses) 12 and making exposed the barrier layer 14 present in the other portion than the interconnect-formed portion, as shown in FIG. 5A. According to this embodiment, the removal of the extra copper 16 is carried out in such a manner that after the surfaces of interconnects 18 in the trenches 12 have become substantially flush with the surface of the exposed barrier layer 14, polishing or etching of interconnects 18 is further continued so that the surfaces of interconnects 18 formed in the trenches 12 become lower than the surface of the exposed barrier layer 14, and the distance D1 between the surface of the barrier layer 14 and the surfaces of interconnects 18 becomes almost equal to the sum of the thickness T₁ of the barrier layer 14, the thickness T₂ (see FIG. 5B) of a metal film 20 to be formed on the surfaces of interconnects 18 and the removal thickness ΔT (see FIG. 5B) of the insulating film 10 (D≈T₁+T₂+ΔT). For example, when the thickness T₁ of the barrier layer 14 is 10 nm and the necessary thickness T₂ of the metal film 20 is 10 nm, the distance D₁ between the surface of the barrier layer 14 and the surfaces of interconnects 18 is made equal to the sum of 20 nm and the removal thickness ΔT of the insulating film 10.

Using the barrier layer 14 thus left as a mask, a metal film (protective film) 20 of, for example, a cobalt alloy or a nickel alloy is formed selectively on the surfaces of interconnects 18 in the trenches 12, as shown in FIG. 5B, thereby covering the surfaces of interconnects 18 with the metal film 20 to protect interconnects 18.

Next, the barrier layer 14 on the insulating film 10, exposed on the surface of the substrate W, is selectively removed by CMP or etching, and then the insulating film 10 is partly removed by a removal thickness ΔT, thereby completing the formation of interconnects 18 of copper whose surfaces are selectively covered and protected with the metal film 20, as shown in FIG. 5C. By thus partly removing the insulating film 10 after the removal of the barrier layer 14 on the insulating film 10, the barrier layer 14 on the insulating film 10 can be completely removed, thus preventing part of the barrier layer 14 from remaining on the insulating film 10.

By making the distance D₁ between the surface of the barrier layer 14 and the surfaces of interconnects 18 after the removal of the unnecessary copper almost equal to the sum of the thickness T₁ of the barrier layer 14, the thickness T₂ of the metal film 20 to be formed on the surfaces of interconnects 18 and the removal thickness ΔT of the insulating film 10, as described above, the surface of the substrate W, after the removal of the barrier layer 14 which has become unnecessary and the partial removal of the insulating film 10 by the removal thickness ΔT, can be made flat.

The metal film 20 has been formed on the surfaces of interconnects 18 to protect interconnects 18 prior to the partial removal of the insulating film 10. Accordingly, as with the case of the barrier layer 14, the insulating film 10 can be removed by a method with a relatively small mechanical factor. For example, the insulating film 10 can be removed by etching with a chemical or plasma etching without resorting to a mechanical factor.

It is also possible to make the distance D₁ between the surface of the barrier layer 14 and the surfaces of interconnects 18 after the removal of the unnecessary copper larger than the sum of the thickness T₁ of the barrier layer 14, the thickness T₂ of the metal film 20 to be formed on the surfaces of interconnects 18 and the removal thickness ΔT of the insulating film 10 (D₁>ΔT+T₁+T₂). This can prevent the interconnect portion, consisting of interconnects 18 and the metal film 20 formed thereon, from protruding from the substrate surface after the removal of the barrier layer 14 and the partial removal of the insulating film 10.

It is, of course, possible also with the embodiments shown in FIGS. 3A through 3C and FIGS. 4A through 4C to partly remove the insulating film 10 e.g. by etching subsequently to the removal of the barrier layer 14 e.g. by etching, thereby completely removing the barrier layer 14 from the surface of the insulating film 10.

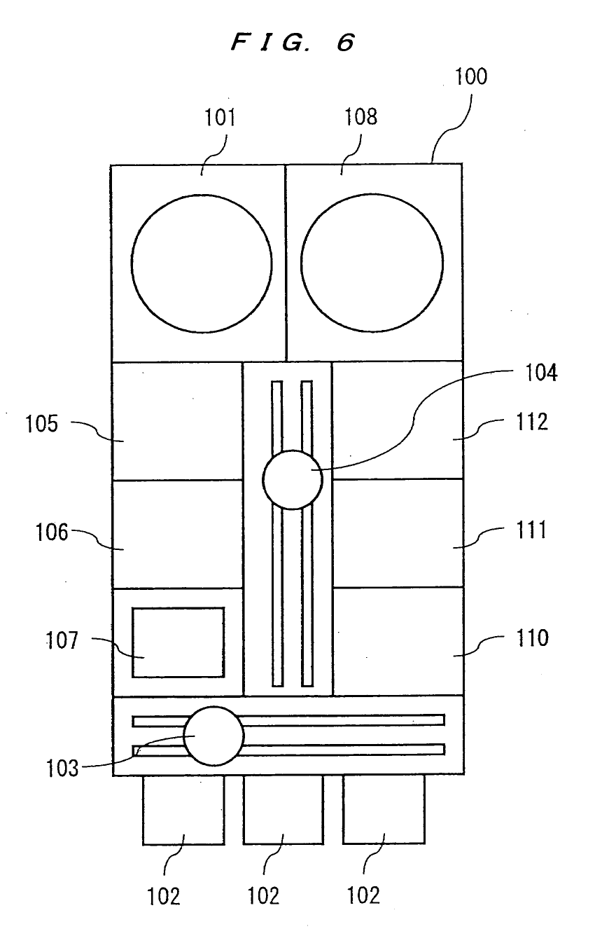

FIG. 6 shows a layout plan view of an interconnects forming apparatus according to an embodiment of the present invention. The interconnects forming apparatus includes, at one end of the space on the floor of a housing 100, a pair of opposing chemical-mechanical polishing (CMP) units 101, 108, and at the other end a loading/unloading section for mounting cassettes 102 each for housing substrates W, such as semiconductor wafers. A first transport robot 103 and a second transport robot 104 are disposed between the polishing units 101, 108 and the loading/unloading section. The apparatus also includes, on one side of the transport line, a first cleaning unit 105 provided with a roll sponge or pencil sponge, a second cleaning (rinsing/drying) unit 106 and a temporary storage stage 107, and on the other side a first pretreatment unit 110, a second pretreatment unit 111 and an electroless plating unit 112 for the formation of protective film.

A process of forming interconnects on a substrate W, as shown in FIG. 2, by this interconnects forming apparatus will now be described by referring to FIGS. 3A through 3C.

First, one substrate W as shown in FIG. 2 is taken by the first transport robot 103 out of the cassette 102 housing such substrates W, and the substrate W is transported to the temporary storage stage 107. The substrate W on the temporary storage stage 107 is taken up by the second transport robot 104 and transported to the polishing unit 101. In the polishing unit 101, extra interconnect material 16 outside the trenches (interconnect recesses) 12 is polished and removed, thereby forming interconnects 18 and making the barrier layer 14 exposed, as shown in FIG. 3A. Though not shown diagrammatically, the polishing is carried out by pressing the surface of the substrate W, held by a top ring, against a polishing table, which has a polishing pad serving as a polishing surface, at a given pressure while supplying a polishing liquid (slurry) onto the polishing surface.

Next, the substrate W after polishing is transported by the second transport robot 104 to the first cleaning unit 105, where the surface of the substrate is cleaned, for example, with a chemical and a roll sponge.

The substrate W after cleaning is transported by the second transport robot 104 to the first pretreatment unit 110. In the first pretreatment unit 110, a cleaning treatment of the substrate surface as a pre-plating treatment is carried out. For example, the entire substrate surface is brought into contact with a chemical such as diluted H₂SO₄ at 25° C., thereby removing CMP residues, such as copper, and an oxide on interconnects, followed by rinsing (cleaning) of the surface of the substrate with a rinsing liquid such as pure water.

Next, the substrate W after the cleaning treatment is transported by the second transport robot 104 to the second pretreatment unit 111. In the second pretreatment unit 111, the substrate W is held face down, and a catalyst application treatment of the surface of the substrate W is carried out. For example, a catalyst solution containing a catalytic metal for the formation of a protective film (metal film) is jetted toward the surface of the substrate W to thereby activate the surfaces of interconnects 18, followed by rinsing (cleaning) of the surface of the substrate W with a rinsing liquid such as pure water.

The substrate W after the catalyst application treatment is transported by the second transport robot 104 to the electroless plating unit 112, where electroless plating of the surface of the substrate is carried out to form the metal film (protective film) 20 (see FIG. 3B). In particular, the substrate W, held face down, is lowered toward the liquid surface of an electroless plating solution held in a plating tank and the surface of the substrate is brought into contact with the plating solution. After an elapse of a predetermined time, the substrate is pulled up from the plating solution, and a neutral stop liquid with a pH of 6-7.5 is brought into contact with the surface of the substrate W to thereby stop electroless plating. Though not shown diagrammatically, it is possible to provide a third pretreatment unit, for carrying out pH adjustment (neutralization treatment) of the surface of the substrate W after the catalyst application, between the second pretreatment unit 111 and the electroless plating unit 112.

Next, the substrate W after the formation of the metal film is transported by the second transport robot 104 to the polishing unit 108, where the entire surface of the substrate W is polished to remove the unnecessary barrier layer 14 (see FIG. 3C). A polishing liquid (slurry) having a higher polishing rate for the barrier layer than for the metal film (protective film) may preferably be used in the polishing.

The substrate W after polishing is transported by the second transport robot 104 to the first cleaning unit 105, where a chemical containing a surfactant, an organic alkali, a chelating agent, etc. is supplied from a supply nozzle to the surface of the substrate to carry out roll scrub cleaning or cleaning only with the chemical. In the case of cleaning treatment with the chemical, the chemical remaining on the surface of the substrate W is rinsed with a rinsing liquid such as pure water.

The substrate W after cleaning is transported by the second transport robot 104 to the second cleaning (rinsing/drying) unit 106, where the substrate W is rinsed and is then rotated at a high speed for spin-drying. The dried substrate W is transported by the second transport robot 104 to the temporary storage stage 107. The substrate W on the temporary storage stage 107 is taken up by the first transport robot 103 and transported into the cassette 102, thereby completing the interconnects forming process.

The series of processings for the formation of embedded interconnects, having the metal film (protective film) 20 formed thereon, in the surface of the substrate W can thus be carried out successively.

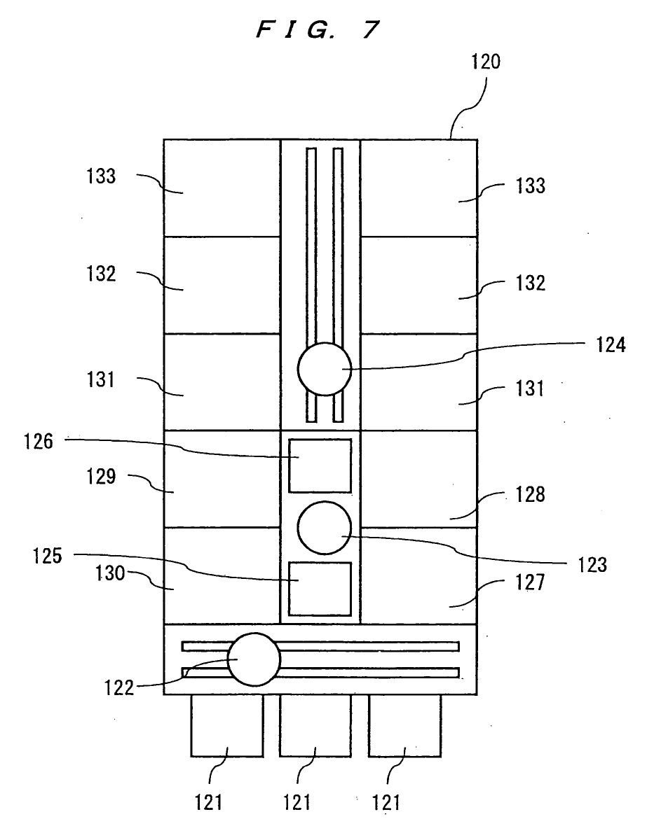

FIG. 7 shows a layout plan view of an interconnects forming apparatus according to another embodiment of the present invention. The interconnects forming apparatus includes a housing 120, a loading/unloading section, disposed in the housing 120 at its one end, for mounting cassettes 121 for housing substrates W, and, disposed in the following order toward the other end of the housing 120, a first transport robot 122, a temporary storage stage 125, a second transport robot 123, a temporary storage stage 126 and a third transport robot 124. The first transport robot 122 transports a substrate W between the cassettes 121 and the temporary storage stage 125. The second transport robot 123 transports the substrate W between the temporary storage stage 125, the temporary storage stage 126, a first wet etching unit 127, a second wet etching unit 128, a first cleaning unit 129 and a second cleaning unit 130, all disposed around the second transport robot 123. The third transport robot 124 transports the substrate W between the temporary storage stage 126, first pretreatment units 131, 131, second pretreatment units 132, 132 and electroless plating units 133, 133, the units 131 to 133 being for the formation of protective film.

According to this embodiment, one substrate W as shown in FIG. 2 is taken by the first transport robot 122 out of the cassette 121 housing such substrates W, and the substrate W is transported to the temporary storage stage 125. The substrate W on the temporary storage stage 125 is taken up by the second transport robot 123 and transported to the first wet etching unit 127. In the first wet etching unit 127, extra interconnect material 16 outside the interconnect recesses 12 is removed by etching with a chemical, thereby forming interconnects 18 and making the barrier layer 14 exposed, as shown in FIG. 4A. The surfaces of interconnects 18 formed in the trenches 12 may be made lower than the top surface of the insulating film 10.

The substrate W is transported by the second transport robot 123 to the first cleaning unit 129, where the substrate surface is cleaned, for example, by roll scrub cleaning. Thereafter, the substrate W is transported by the second transport robot 123 to the temporary storage stage 126. Depending upon the process requirements, the substrate W may be transported from the first cleaning unit 129 to the second cleaning unit 130 to carry out a second-step cleaning before the substrate W is transported to the temporary storage stage 126.

The substrate W on the temporary storage stage 126 is transported by the third transport robot 124 to the first pretreatment unit 131, where a cleaning treatment of the substrate surface as a pre-plating treatment is carried out. Thereafter, the substrate W is transported by the third transport robot 124 to the second pretreatment unit 132 and then to the electroless plating unit 133 to carry out pretreatment and electroless plating of the surface of the substrate in the same manner as in the preceding embodiment, thereby forming a metal film (protective film) 20 shown in FIG. 4B on interconnects 18 of the substrate W. In case the surfaces of interconnects 18 formed in the trenches 12 in the substrate surface is lower than the top surface of the insulating film 10, the metal film 20 is preferably made to have such a thickness that the surface of the metal film 20 is substantially flush with the top surface of the insulating film 10.

The substrate W after completion of the electroless plating is transported by the third transport robot 124 onto the temporary storage stage 126. The substrate W on the temporary storage stage 126 is then transported by the second transported robot 123 to the first cleaning unit 129 for cleaning of the substrate. After further cleaning the substrate in the second cleaning unit 130, according to necessity, the substrate W is transported to the second wet etching unit 128. In the second wet etching unit 128, an etching liquid is supplied to the entire surface of the substrate W to etch the barrier layer 14 until the insulating film 10 becomes exposed on the substrate surface, as shown in FIG. 4C.

The substrate W after completion of the etching of barrier layer 14 is transported to the first cleaning unit 129, where the substrate surface is cleaned e.g. by roll scrub cleaning. The substrate W after cleaning is transported to the second cleaning unit 130, where the substrate W is rinsed and then rotated at a high speed for spin-drying. The dried substrate W is placed on the temporary storage stage 125, and the substrate W is then placed in the cassette 121 by the first transport 122, thereby completing the interconnects forming process.

According to this apparatus, the series of processings for the formation of embedded interconnects having the protective film 20 can be carried out successively without applying a mechanical stress to the substrate surface which can be composed of a weak material.

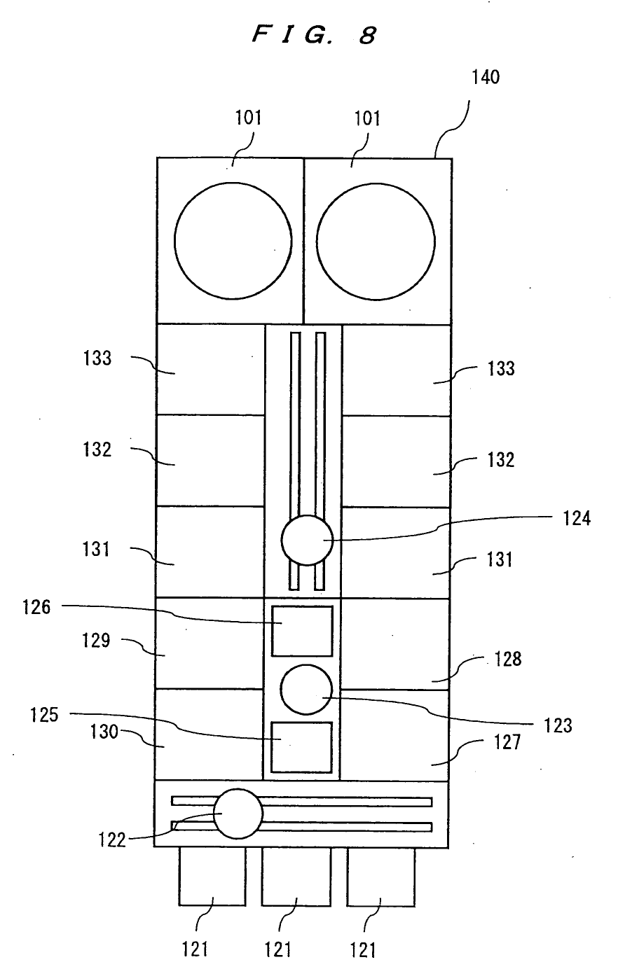

FIG. 8 shows a layout plan view of an interconnects forming apparatus according to yet another embodiment of the present invention. This apparatus includes, in addition to the units shown in FIG. 7, polishing units 101 disposed in a housing 140 at a location accessible by the third transport robot 124.

According to this apparatus, in carrying out the interconnects forming method of the present invention, the removal of the copper film (interconnect material) 16 can be performed by the polishing unit 101, and the removal of the barrier layer 14 after electroless plating can be performed by the wet etching unit 127 or 128. Alternatively, the removal of the copper film (interconnect material) 16 can be performed by the wet etching unit 127 or 128, and the removal of the barrier layer 14 after electroless plating can be performed by the polishing unit 101. Either manner can provide the substrate W with a flat finished surface.

According to the present invention, a metal film is formed by using a barrier layer left unremoved, which is free from the problem of poor wettability, as a mask. This makes it possible to form the metal film selectively on surfaces of interconnects without changing the process conditions depending on the material of an insulating film. Furthermore, a barrier layer that has become unnecessary and optionally also an insulating film can be removed securely by a method with a relatively small mechanical factor.

1. An interconnects forming method comprising:
providing a substrate which has been prepared by forming a barrier layer over a substrate surface having interconnect recesses formed in an insulating film, and then forming a film of an interconnect material in the interconnect recesses and over the substrate surface;
removing extra interconnect material formed over the substrate surface, thereby forming interconnects with the interconnect material embedded in the interconnect recesses and making the barrier layer present in the other portion than the interconnect-formed portion exposed; and
forming a metal film selectively on surfaces of interconnects.

2. The interconnects forming method according to claim 1, wherein the removal of extra interconnect material from the substrate surface is carried out in such a manner that the surfaces of interconnects formed in the interconnect recesses becomes lower than the surface of the insulating film.

3. The interconnects forming method according to claim 1, wherein the metal film is formed by a chemical vapor deposition method.

4. The interconnects forming method according to claim 1, wherein the metal film is formed by a plating method.

5. The interconnects forming method according to claim 1, wherein the barrier layer on the insulating film is removed after the selective formation of the metal film on the surfaces of interconnects.

6. The interconnects forming method according to claim 5, wherein the removal of the barrier layer on the insulating film is carried out by polishing.

7. The interconnects forming method according to claim 5, wherein the removal of the barrier layer on the insulating film is carried out by etching with a chemical.

8. The interconnects forming method according to claim 5, wherein the removal of the barrier layer on the insulating film is carried out by plasma etching.

9. The interconnects forming method according to claim 2, wherein the selective formation of the metal film on the surfaces of interconnects is carried out in such a manner that the surface of the metal film remains lower than the surface of the insulating film.

10. The interconnects forming method according to claim 5, wherein after the removal of the barrier layer on the insulating film, the insulating film is partly removed.

11. The interconnects forming method according to claim 10, wherein the partial removal of the insulating film is carried out in such a manner that the surface of the insulating film and the surface of the metal film make a substantially flat plane.

12. The interconnects forming method according to claim 10, wherein the removal of the insulating film is carried out by etching with a chemical.

13. The interconnects forming method according to claim 10, wherein the removal of the insulating film is carried out by plasma etching.

14. An interconnects forming apparatus comprising:
a loading/unloading section for mounting a cassette for housing a substrate;
a transport robot for transporting the substrate;
a wet etching unit for etching an entire surface of the substrate with a chemical;
a pretreatment unit for carrying out a pre-electroless plating treatment of the surface of the substrate;
an electroless plating unit for carrying out electroless plating of the surface of the substrate; and
a cleaning unit for cleaning the surface of the substrate.

15. The interconnects forming apparatus according to claim 14 further comprising a chemical-mechanical polishing unit.
